(19) United States
(12) Patent Application Publication
(10) Pub. No.: US 2004/0152297 A1
(43) Pub. Date: Aug. 5, 2004

(54) Semiconductor device and manufacturing method thereof

(75) Inventors: Kenichi Ooto, Hyogo (JP); Masahiko Takeuchi, Hyogo (JP); Yoshinori Tanaka, Hyogo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/623,512

(22) Filed: Jul. 22, 2003

(30) Foreign Application Priority Data
Feb. 4, 2003 (JP) 2003-026904(P)

(51) Int. Cl. H01L 21/4763

(52) U.S. Cl. 438/629; 257/774

(57) ABSTRACT

A method of manufacturing a semiconductor device includes the steps of: forming an interlayer insulating film covering an upper side of a projected gate portion and a gap between the projected gate portions; forming a contact hole reaching a first bottom portion introduced into a semiconductor substrate, from an upper surface of the interlayer insulating film through the gap between the projected gate portions; forming a second bottom portion having the semiconductor substrate exposed on the bottom face and the side face by forming a diffusion prevention film covering a side face of the first bottom portion and by etching further the bottom face of the first bottom portion; and forming a plug by filling the contact hole with polysilicon having an impurity doped.

### BACKGROUND OF THE INVENTION

### FIELD OF THE INVENTION

The present invention relates to a semiconductor device including a plug electrode, and a manufacturing method thereof.

### DESCRIPTION OF THE BACKGROUND ART

A conventional semiconductor device including a plug electrode composed of polysilicon is disclosed, for example, in Japanese Patent Laying-Open No. 2001-217320 or No. 7-230967. In such a semiconductor device, a gate oxide film is formed on an upper surface of a silicon substrate serving as a semiconductor substrate, and a plurality of gate electrodes in a line shape are formed in parallel on the gate oxide film. A transistor is thus formed, and a plug electrode composed of polysilicon is disposed between the gate electrodes. A lower end of the plug electrode is directly connected to the semiconductor substrate.

In particular, in Japanese Patent Laying-Open No.2001-217320, a trench, that is, a depression, is formed in the semiconductor substrate by etching into the semiconductor substrate. An impurity is then injected to a bottom face and a side face in a lower portion of the trench so as to form a well bias region, and the plug electrode is formed so as to fill the trench, as a contact portion.

When the plug electrode composed of polysilicon having the impurity doped is directly connected to the semiconductor substrate between gate electrodes, the impurity diffuses from polysilicon into the semiconductor substrate, and a source/drain region with high density will be created directly under vicinity areas of opposing ends of the gate electrode. In such a case, GIDL (Gate Induced Drain Leakage) will be likely. Here, “GIDL” refers to a phenomenon, in which, when negative bias and positive bias are applied to the gate electrode and a drain electrode respectively, a depletion layer extends as far as a drain region, where field density will be higher, and electrons cause BTBT (Band To Band Tunneling), resulting in a flow of leak current. In addition, when the impurity diffuses into the semiconductor substrate from polysilicon connected to the semiconductor substrate as the plug electrode, punchthrough of the transistor tends to occur. In other words, what is called “punchthrough resistance” is lowered. Alternatively, likeliness of punchthrough is also called “smaller punchthrough margin”.

On the other hand, a technique is available, in which, after the gate electrode is formed and a sidewall thereof is oxidized, a P-type impurity such as boron is diagonally injected to the source/drain region in the semiconductor substrate exposed between the gate electrodes, so as to improve punchthrough resistance. In this case, however, contact resistance may be increased, because of injection of the P-type impurity in a surface portion of the source/drain region. If the contact resistance increases, a current value in a saturation region in the transistor will be smaller. Therefore, a writing speed of the transistor will be slower.

### SUMMARY OF THE INVENTION

An object of the present invention is to provide a semiconductor device capable of preventing GIDL and maintaining high punchthrough resistance without increasing contact resistance, as well as a manufacturing method thereof.

In order to attain the object as above, a method of manufacturing a semiconductor device according to the present invention includes the steps of: forming a plurality of projected gate portions by forming a plurality of gate electrodes in a line shape in parallel on a gate oxide film formed so as to cover a main surface of a semiconductor substrate and by forming a sidewall spacer serving as an insulating film covering a side of the gate electrode; forming an interlayer insulating film covering an upper side of the projected gate portion and a gap between the projected gate portions, with respect to the projected gate portion; forming a contact hole reaching a first bottom portion introduced into the semiconductor substrate, from an upper surface of the interlayer insulating film through the gap between the projected gate portions; forming a second bottom portion having the semiconductor substrate exposed on a bottom face and a side face by forming a diffusion prevention film covering a side face of the first bottom portion and by etching further a bottom face of the first bottom portion; and forming a plug by filling the contact hole with polysilicon having an impurity doped.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 illustrates a first process step in a manufacturing method of a semiconductor device in Embodiment 1 and the like according to the present invention.

FIG. 2 illustrates a second process step in the manufacturing method of the semiconductor device in Embodiment 1 and the like according to the present invention.

FIG. 3 illustrates a third process step in the manufacturing method of the semiconductor device in Embodiment 1 and the like according to the present invention.

FIG. 4 illustrates a fourth process step in the manufacturing method of the semiconductor device in Embodiment 1 and the like according to the present invention.

FIG. 5 illustrates a fifth process step in the manufacturing method of the semiconductor device in Embodiment 1 and the like according to the present invention.

FIG. 6 illustrates a sixth process step in the manufacturing method of the semiconductor device in Embodiment 1 and the like according to the present invention.

FIG. 7 illustrates a seventh process step in the manufacturing method of the semiconductor device in Embodiment 1 and the like according to the present invention.

FIG. 8 illustrates an eighth process step in the manufacturing method of the semiconductor device in Embodiment 1 and the like according to the present invention.

FIG. 9 illustrates a ninth process step in the manufacturing method of the semiconductor device in Embodiment 1 and the like according to the present invention.

FIG. 10 illustrates a tenth process step in the manufacturing method of the semiconductor device in Embodiment 1 and the like according to the present invention.

FIG. 11 illustrates an eleventh process step in the manufacturing method of the semiconductor device in Embodiment 1 according to the present invention.

FIG. 12 illustrates a twelfth process step in the manufacturing method of the semiconductor device in Embodiment 1 according to the present invention.

FIG. 13 illustrates a thirteenth process step in the manufacturing method of the semiconductor device in Embodiment 1 according to the present invention.

FIG. 14 is a partially enlarged view of FIG. 13.

FIG. 15 is a cross-sectional view of a semiconductor device shown as comparison in Embodiment 1.

FIG. 16 is a cross-sectional view of the semiconductor device during fabrication, illustrating a cavity created by insufficient embedding of an interlayer insulating film in Embodiment 1.

FIG. 17 is a schematic perspective view illustrating the cavity created by insufficient embedding of the interlayer insulating film in Embodiment 1.

FIG. 18 illustrates an eleventh process step in a manufacturing method of a semiconductor device in Embodiment 2 according to the present invention.

FIG. 19 illustrates a twelfth process step in the manufacturing method of the semiconductor device in Embodiment 2 according to the present invention.

FIG. 20 illustrates a thirteenth process step in the manufacturing method of the semiconductor device in Embodiment 2 according to the present invention.

FIG. 21 illustrates a fourteenth process step in the manufacturing method of the semiconductor device in Embodiment 2 according to the present invention.

FIG. 22 illustrates a tenth process step in a manufacturing method of a semiconductor device in Embodiment 3 according to the present invention.

FIG. 23 illustrates an eleventh process step in the manufacturing method of the semiconductor device in Embodiment 3 according to the present invention.

FIG. 24 illustrates a twelfth process step in the manufacturing method of the semiconductor device in Embodiment 3 according to the present invention.

FIG. 25 illustrates a thirteenth process step in the manufacturing method of the semiconductor device in Embodiment 3 according to the present invention.

FIG. 26 is a partially enlarged view of FIG. 25.

FIG. 27 is a cross-sectional view of a semiconductor device obtained by a method of manufacturing a semiconductor device in Embodiment 4 of the present invention.

FIG. 28 illustrates a tenth process step in a manufacturing method of a semiconductor device in Embodiment 5 according to the present invention.

FIG. 29 illustrates an eleventh process step in the manufacturing method of the semiconductor device in Embodiment 5 according to the present invention.

FIG. 30 illustrates a sixth process step in a manufacturing method of a semiconductor device in Embodiments 6 and 8 according to the present invention.

FIG. 31 illustrates an eleventh process step in the manufacturing method of the semiconductor device in Embodiment 6 according to the present invention.

FIG. 32 illustrates a twelfth process step in the manufacturing method of the semiconductor device in Embodiment 6 according to the present invention.

FIG. 33 illustrates a thirteenth process step in the manufacturing method of the semiconductor device in Embodiment 6 according to the present invention.

FIG. 34 is a partially enlarged view of FIG. 33.

FIG. 35 illustrates a sixth process step in a manufacturing method of a semiconductor device in Embodiments 7 and 9 according to the present invention.

FIG. 36 illustrates a seventh process step in the manufacturing method of the semiconductor device in Embodiment 7 according to the present invention.

FIG. 37 illustrates an eighth process step in the manufacturing method of the semiconductor device in Embodiment 7 according to the present invention.

FIG. 38 illustrates a ninth process step in the manufacturing method of the semiconductor device in Embodiment 7 according to the present invention.

FIG. 39 illustrates a tenth process step in the manufacturing method of the semiconductor device in Embodiment 7 according to the present invention.

FIG. 40 is a partially enlarged view of FIG. 39.

FIG. 41 illustrates a seventh process step in a manufacturing method of a semiconductor device in Embodiment 8 according to the present invention.

FIG. 42 illustrates an eighth process step in the manufacturing method of the semiconductor device in Embodiment 8 according to the present invention.

FIG. 43 illustrates a ninth process step in the manufacturing method of the semiconductor device in Embodiment 8 according to the present invention.

FIG. 44 illustrates a tenth process step in the manufacturing method of the semiconductor device in Embodiment 8 according to the present invention.

FIG. 45 is a partially enlarged view of FIG. 44.

FIG. 46 illustrates a seventh process step in a manufacturing method of a semiconductor device in Embodiment 9 according to the present invention.

FIG. 47 illustrates an eighth process step in the manufacturing method of the semiconductor device in Embodiment 9 according to the present invention.

FIG. 48 illustrates a ninth process step in the manufacturing method of the semiconductor device in Embodiment 9 according to the present invention.

FIG. 49 illustrates a tenth process step in the manufacturing method of the semiconductor device in Embodiment 9 according to the present invention.

FIG. 50 illustrates an eleventh process step in the manufacturing method of the semiconductor device in Embodiment 9 according to the present invention.

FIG. 51 is a partially enlarged view of FIG. 50.

### DESCRIPTION OF THE PREFERRED EMBODIMENTS

### Embodiment 1

A manufacturing method of a semiconductor device in Embodiment 1 according to the present invention will be described with reference to the figures.

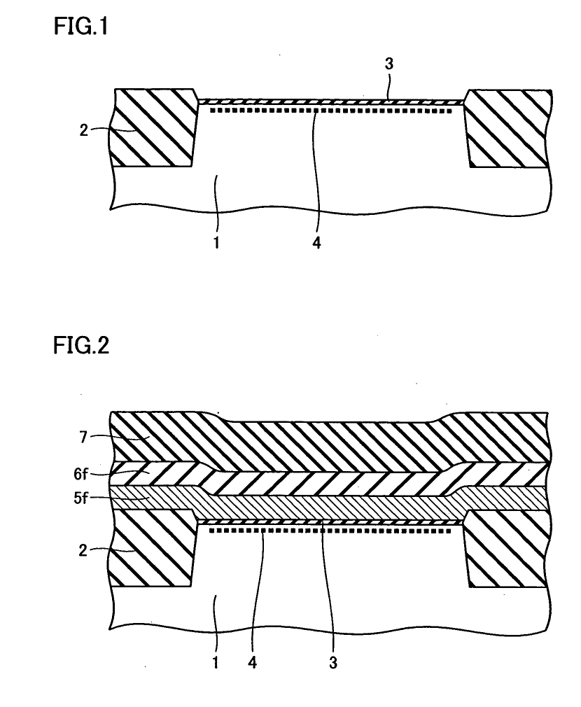

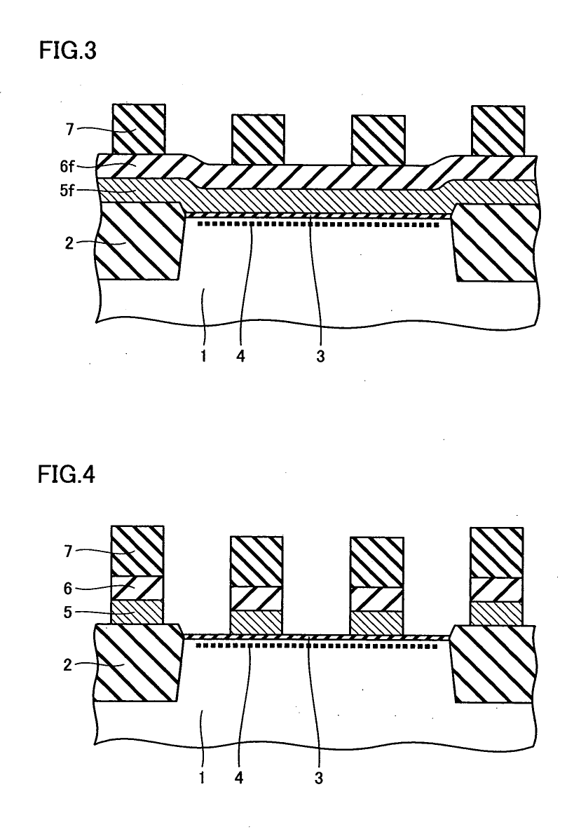

As shown in FIG. 1, an isolation oxide film 2 is locally formed on an upper surface of a semiconductor substrate 1 which is a P-type silicon substrate. A gate oxide film 3 is formed in a position which is not covered with isolation oxide film 2 on the upper surface of semiconductor substrate 1. A channel layer 4 is formed by injecting a P-type impurity such as B or BF₂ as a channel dope. In order to cover those components, as shown in FIG. 2, a polysilicon layer 5f, which is a material for the gate electrode, and a WSi film 6f are formed to a total thickness of 150 nm. Then, a nitride film 7 is successively deposited to a thickness of 160 nm thereon. A resist film pattern is formed with photolithography, followed by anisotropic dry etching, to remove the resist film. Thus, as shown in FIG. 3, nitride film 7 is patterned. Using nitride film 7 as a mask, anisotropic dry etching is further performed, to form a gate electrode 5, as shown in FIG. 4. WSi film 6f becomes a WSi film 6 that has a size almost similar to gate electrode 5 and covers an upper side thereof. A side face of gate electrode 5 and WSi film 6 is oxidized to form a sidewall oxide film 8, as shown in FIG. 5. Further, a source/drain region 9 is formed by injecting an N-type impurity such as P or As, as shown in FIG. 5.

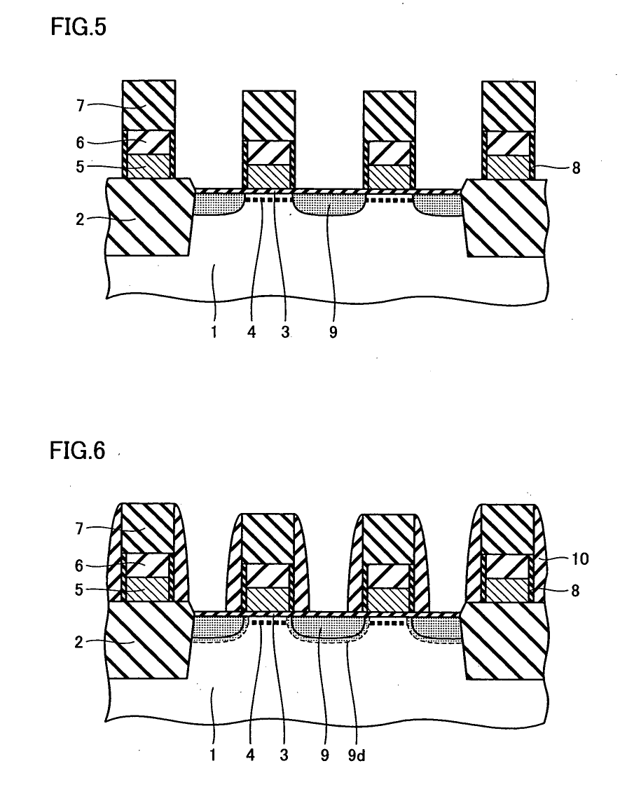

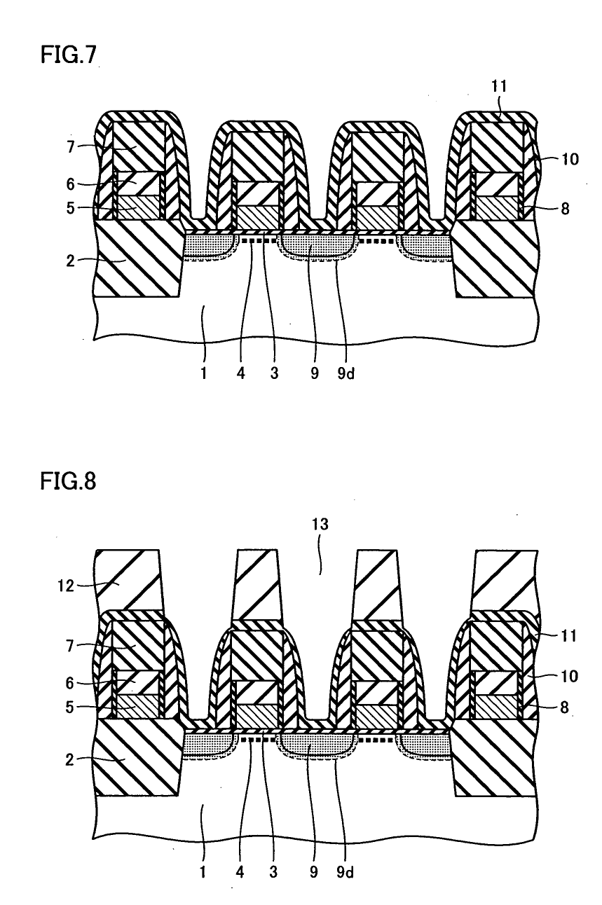

The nitride film is deposited on the entire surface to a thickness of 20 nm, and is subjected to anisotropic dry etching. Accordingly, a sidewall spacer 10 is formed as shown in FIG. 6. Anisotropic dry etching is performed so as to stop at a stage where gate oxide film 3 is exposed. Deposition of the nitride film used as a material for sidewall spacer 10 involves heat treatment, however, due to the heat treatment, the impurity tends to diffuse from source/drain region 9 into semiconductor substrate 1 as shown in FIG. 6, resulting in a diffusion portion 9d. Next, as shown in FIG. 7, a nitride film 11 serving as a stopper film is deposited on an overall surface to a thickness of 15 nm.

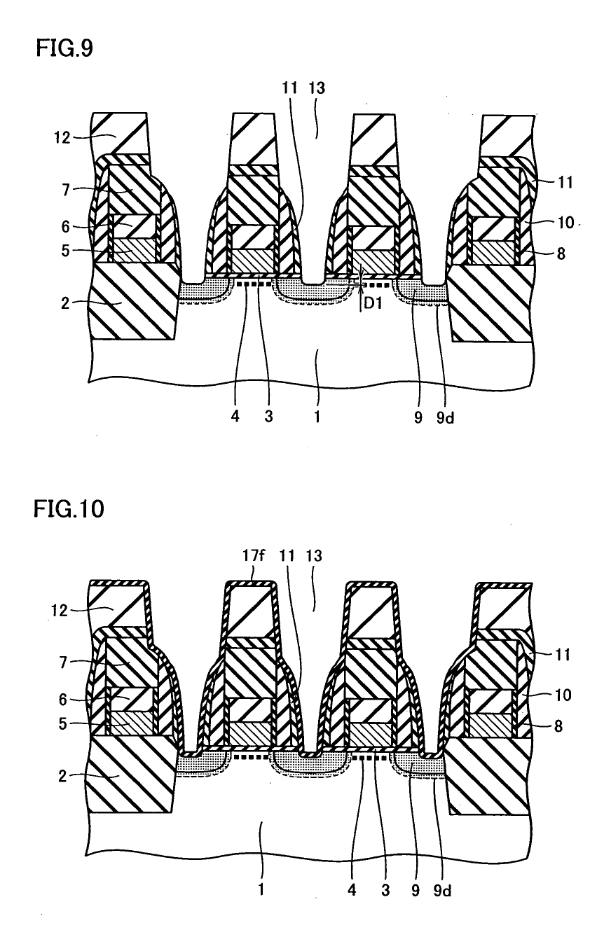

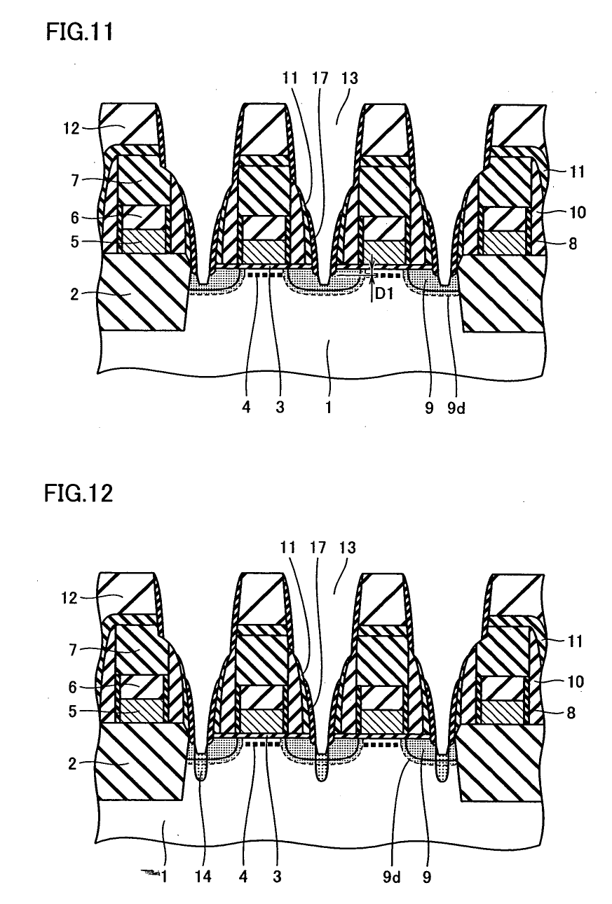

In addition, an interlayer insulating film 12 composed of BPTEOS (Boro Phospho Tetra-Ethyl Ortho Silicate) is deposited to a thickness of 500 nm, so as to cover the overall surface. With photolithography and anisotropic dry etching, a contact hole 13 is formed, as shown in FIG. 8. Etching for forming contact hole 13 once stops at nitride film 11, because of a function of nitride film 11 as the stopper film. Here, anisotropic dry etching is further performed to remove nitride film 11 that has covered a bottom face of contact hole 13, and etching is performed up to such a depth that semiconductor substrate 1 is etched to some extent, as shown in FIG. 9. For example, etching is performed until depth D1 in FIG. 9 attains to approximately 20 nm. Here, for the sake of convenience of illustration, a bottom portion of contact hole 13 is referred to as a “first bottom portion”. “Depth D1” represents a depth from the upper surface of semiconductor substrate 1 to the bottom face of the first bottom portion, as shown in FIG. 9. With such a state, as shown in FIG. 10, a nitride film 17f is deposited to a thickness of approximately 5 nm on the entire surface.

Next, nitride film 17f is subjected to anisotropic dry etching on the overall surface, and a diffusion prevention film 17 is formed by a remaining portion of nitride film 17f, as shown in FIG. 11. Consequently, the lower end of diffusion prevention film 17 is positioned in the first bottom portion, and hence, the lower end reaches a position lower by D1 than the upper surface of semiconductor substrate 1 in other regions. In anisotropic dry etching for forming diffusion prevention film 17, semiconductor substrate 1 is etched to a position deeper by approximately 30 nm from the lower end of diffusion prevention film 17. For the sake of convenience of illustration, the bottom portion of contact hole 13 at this time is referred to as a “second bottom portion”.

Next, as shown in FIG. 12, an N-type impurity such as P is injected into semiconductor substrate 1 exposed in the second bottom portion. In this manner, an N-type impurity region 14 is formed under contact hole 13. Though a nitride film is employed as diffusion prevention film 17 here, an oxide film instead of the nitride film, or alternatively, a combination of the oxide film and the nitride film may be used.

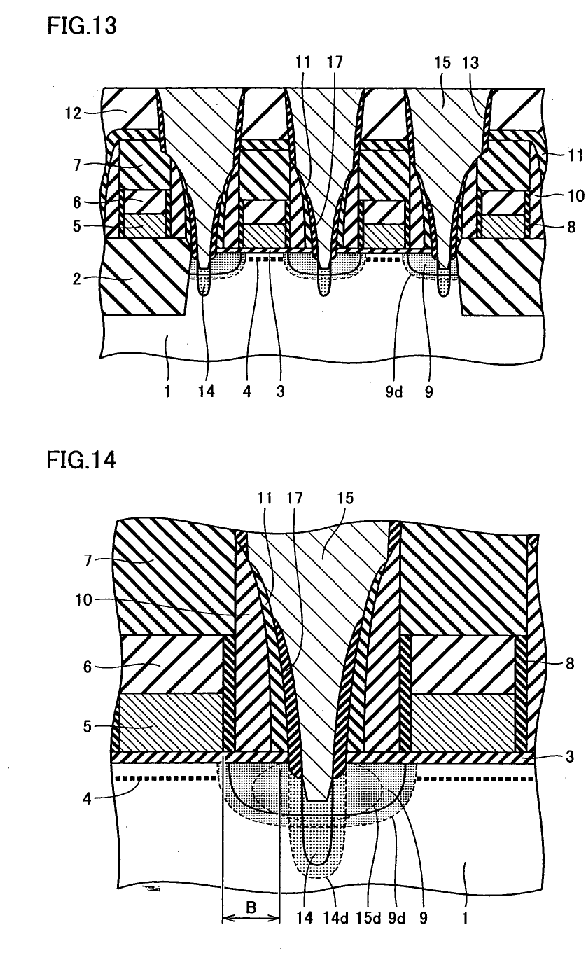

Polysilicon used as a material for the plug is deposited to a thickness of 300 nm. This polysilicon is doped with the N-type impurity such as P or As to a density of 4×10²⁰ cm⁻³. A plug 15 is formed within contact hole 13 by CMP (Chemical Mechanical Polishing) or entire-surface etch back, as shown in FIG. 13. An enlarged view of the vicinity of the bottom portion of contact hole 13 in FIG. 13 is shown in FIG. 14. The impurity diffuses from each of an N-type impurity region 14, source/drain region 9 and plug 15, and diffusion portions 14d, 9d, and 15d are produced respectively.

The semiconductor device in the present embodiment includes a plurality of gate electrodes 5 formed in a line shape in parallel on semiconductor substrate 1, with gate oxide film 3 as the gate insulating film interposed, as shown in FIGS. 13 and 14. In addition, the semiconductor device includes plug 15 formed with polysilicon having the N-type impurity doped in a gap between gate electrodes 5, so that the lower end of the plug is introduced into semiconductor substrate 1. Moreover, the semiconductor device includes diffusion prevention film 17 extending so as to cover the side face of plug 15 in the vicinity of the lower end of plug 15 and so as to be introduced into semiconductor substrate 1.

Preferably, N-type impurity region 14 having the N-type impurity injected in a portion in contact with the lower end of plug 15 in semiconductor substrate 1 is provided, as in the present semiconductor device.

In the semiconductor device obtained by the manufacturing method of the semiconductor device in the present embodiment, or in the semiconductor device in the present embodiment, diffusion prevention film 17 extends downward so as to be introduced into semiconductor substrate 1. Therefore, diffusion from plug 15 to semiconductor substrate 1 takes place only from a portion where plug 15 extends lower than diffusion prevention film 17. Accordingly, as can be seen from the shape of diffusion portion 15d in FIG. 14, diffusion along the surface of semiconductor substrate 1 is suppressed to a small area. As a result, distance B from an end of gate electrode 5 to diffusion portion 15d along the surface of semiconductor substrate 1 is larger than distance A to a diffusion portion 15d1, in which case diffusion prevention film 17 is not present in the semiconductor structure (see FIG. 15). In the present embodiment, as distance B is long, punchthrough is unlikely. In other words, punchthrough resistance is high.

In addition, plug 15 is shielded from outside on the surface of semiconductor substrate 1, because diffusion prevention film 17 is introduced into semiconductor substrate 1. Therefore, even if negative bias and positive bias are applied to the gate electrode and the drain electrode respectively, occurrence of BTBT can be suppressed, and GIDL can be prevented.

Moreover, the semiconductor substrate is etched further by approximately 30 nm from the first bottom portion, and plug 15 is connected to semiconductor substrate 1 in the second bottom portion where semiconductor substrate 1 is exposed on the bottom face and the side face. Therefore, large contact area between plug 15 and semiconductor substrate 1 can be ensured, and contact resistance can be lowered.

Diffusion prevention film 17 has been formed with the nitride film in the embodiment described above. The nitride film would be preferable, because it has resistance against hydrofluoric acid treatment performed on an inner face of contact hole 13 before plug 15 is formed. On the other hand, when the oxide film instead of nitride film is employed as a material for diffusion prevention film 17, stress on semiconductor substrate 1 is mitigated, and a hot carrier property is improved, which is preferable.

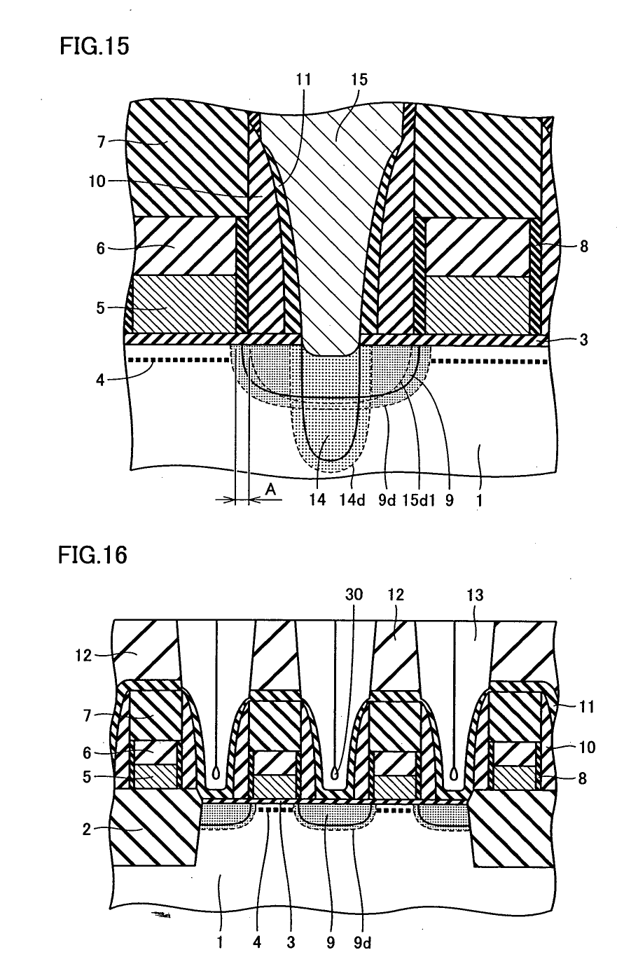

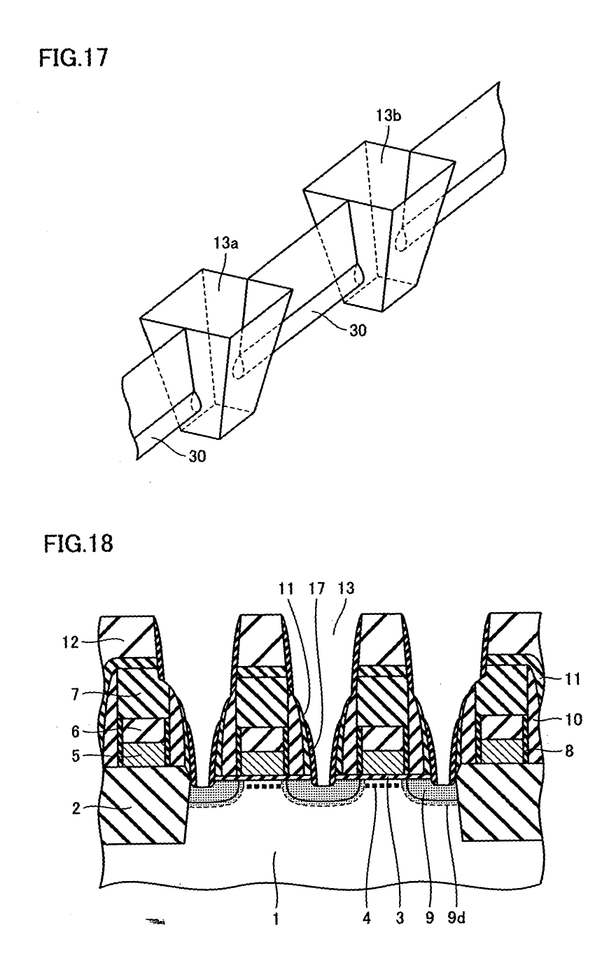

Meanwhile, when interlayer insulating film 12 is deposited on the semiconductor device in a state shown in FIG. 7, in some cases, a cavity may remain inside a narrow trench portion as a result of insufficient embedding. If there is a cavity created due to the insufficient embedding, a cavity 30 appears in a wall of contact hole 13 as actually shown in FIG. 16 at a time point when contact hole 13 is formed in interlayer insulating film 12 as shown in FIG. 8. Though FIG. 8 does not show the wall in the back of contact hole 13, FIG. 16 does show this wall. FIG. 17 schematically and three-dimensionally shows a geometric relation between cavity 30 and contact hole 13. It is to be noted that FIG. 17 shows two contact holes 13a, 13b arranged in line in a direction forward from the back on the sheet in FIG. 16. As shown in FIG. 17, contact holes 13a, 13b arranged with a space apart from each other are connected by cavity 30. If the material for plug 15 (hereinafter, referred to as “plug material”) is filled in each contact hole, the plug material will be deposited also in cavity 30. As a result, plugs are electrically connected to each other, even though they are spaced apart from each other.

In the present embodiment, however, nitride film 17f as the material for diffusion prevention film 17 serving as the insulating film is formed on the entire surface before plug 15 fills contact hole 13, as shown in FIG. 10. Therefore, cavity 30 is filled in advance with the material for the insulating film. Since filling with plug 15 takes place thereafter, the plug material cannot be introduced into cavity 30. Consequently, electric connection between plugs via cavity 30 can be prevented.

In the present semiconductor device, N-type impurity region 14 is provided in the portion in contact with the lower end of plug 15. Therefore, contact resistance between plug 15 and semiconductor substrate 1 is lowered.

### Embodiment 2

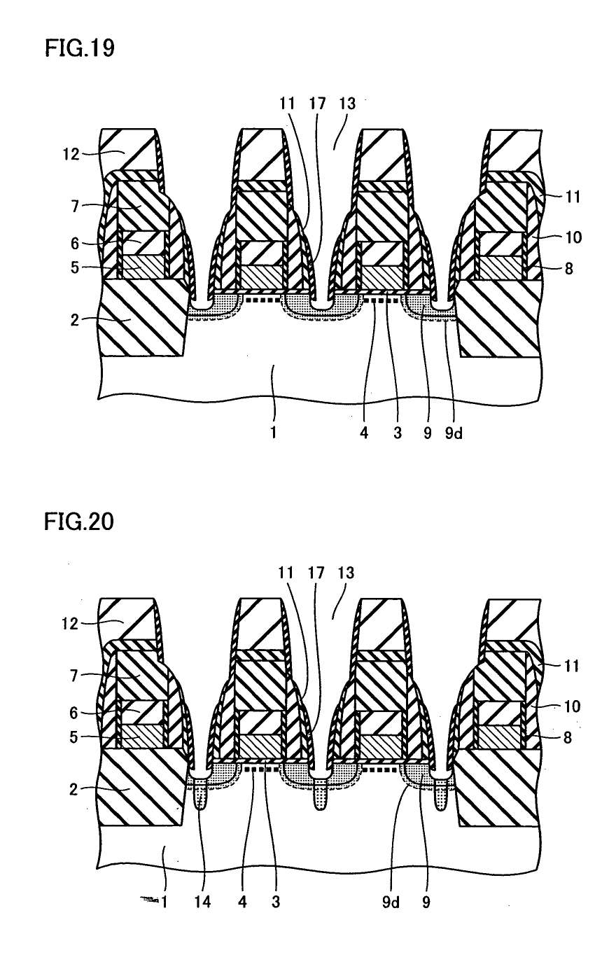

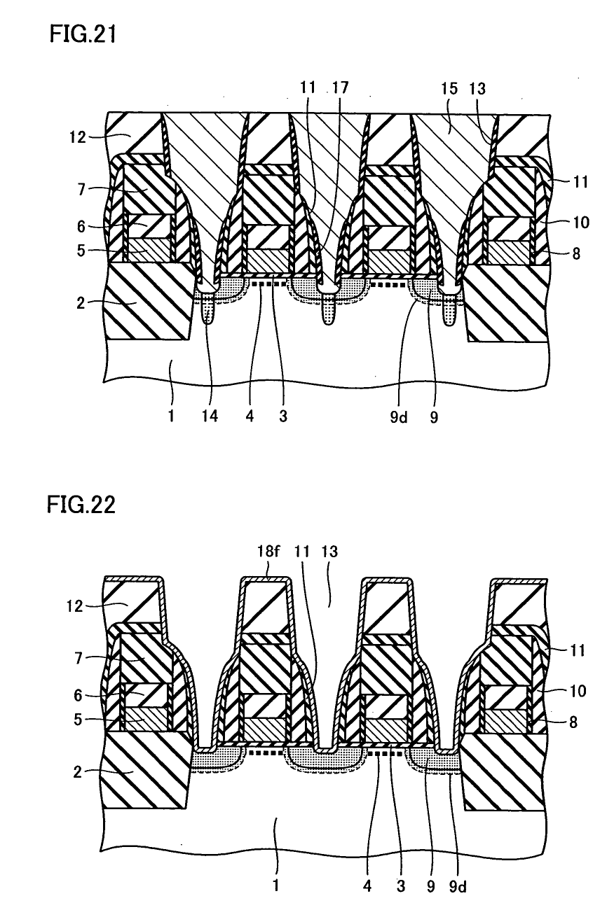

Referring to FIGS. 1 to 10 and 18 to 21, a manufacturing method of a semiconductor device in Embodiment 2 according to the present invention will be described. The process steps shown in FIGS. 1 to 10 are similar to those described in Embodiment 1. In Embodiment 1, anisotropic dry etching has been performed to remove nitride film 17f on the bottom face with respect to the structure in FIG. 10, and in addition, semiconductor substrate 1 has been etched further by approximately 30 nm (see FIG. 11). In the present embodiment, however, though anisotropic etching is performed on the structure in FIG. 10, it is stopped at the stage where semiconductor substrate 1 is exposed by removing nitride film 17f on the bottom face of the contact hole, as shown in FIG. 18. At this time point, diffusion prevention film 17 is formed by the remaining portion of nitride film 17f. In addition, semiconductor substrate 1 exposed on the bottom face of contact hole 13 is subjected to wet etching. As wet etching progresses in an isotropic manner, the bottom portion of contact hole 13 is etched also laterally, to attain a shape as shown in FIG. 19. Then, the N-type impurity such as P is injected to semiconductor substrate 1 exposed on the bottom portion of contact hole 13. In this manner, N-type impurity region 14 is formed under contact hole 13, as shown in FIG. 20. Similarly to Embodiment 1, polysilicon doped with the N-type impurity is deposited as the plug material. Thus, plug 15 as shown in FIG. 21 is formed.

In the present embodiment, after semiconductor substrate 1 is exposed on the bottom portion of the contact hole, not anisotropic dry etching but wet etching is employed for further etching. When the semiconductor substrate is exposed to plasma in anisotropic dry etching, for example, the semiconductor substrate is damaged. On the other hand, in wet etching, the semiconductor substrate can be etched without being exposed to plasma, and accordingly, damage to the semiconductor substrate can be reduced.

In addition, as the wet etching progresses in an isotropic manner, an area of the semiconductor substrate exposed on the bottom portion of the contact hole will be larger, as shown in FIG. 19. Therefore, a large contact area between the plug and the semiconductor device can be ensured, and contact resistance can be reduced.

An effect described in Embodiment 1 can also be obtained in the present embodiment.

### Embodiment 3

Referring to FIGS. 1 to 9 and 22 to 26, a manufacturing method of a semiconductor device in Embodiment 3 according to the present invention will be described. The process steps shown in FIGS. 1 to 9 are similar to those described in Embodiment 1. In Embodiment 1, nitride film 17f has been deposited to a thickness of approximately 5 nm on the entire surface of the structure in FIG. 9 (see FIG. 10). In the present embodiment, however, instead of nitride film 17f, polysilicon doped with boron which is the P-type impurity is deposited to a thickness of approximately 5 nm on the entire surface. Thus, as shown in FIG. 22, a structure covered with a boron-doped polysilicon film 18f is obtained.

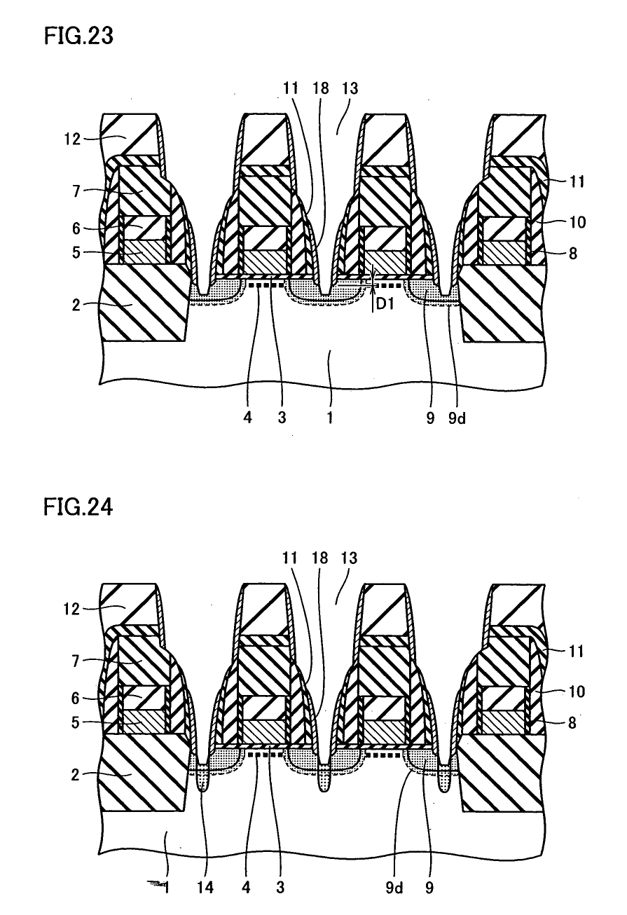

Next, anisotropic dry etching is performed on boron-doped polysilicon film 18f on the entire surface, and a diffusion prevention film 18 is formed by the remaining portion of boron-doped polysilicon film 18f as shown in FIG. 23. As a result, the lower end of diffusion prevention film 18 will be introduced to a position lower by D1 from the upper surface of semiconductor substrate 1 in other regions. In anisotropic dry etching for forming diffusion prevention film 18, semiconductor substrate 1 is further etched to a position by approximately 30 nm deeper than the lower end of diffusion prevention film 18.

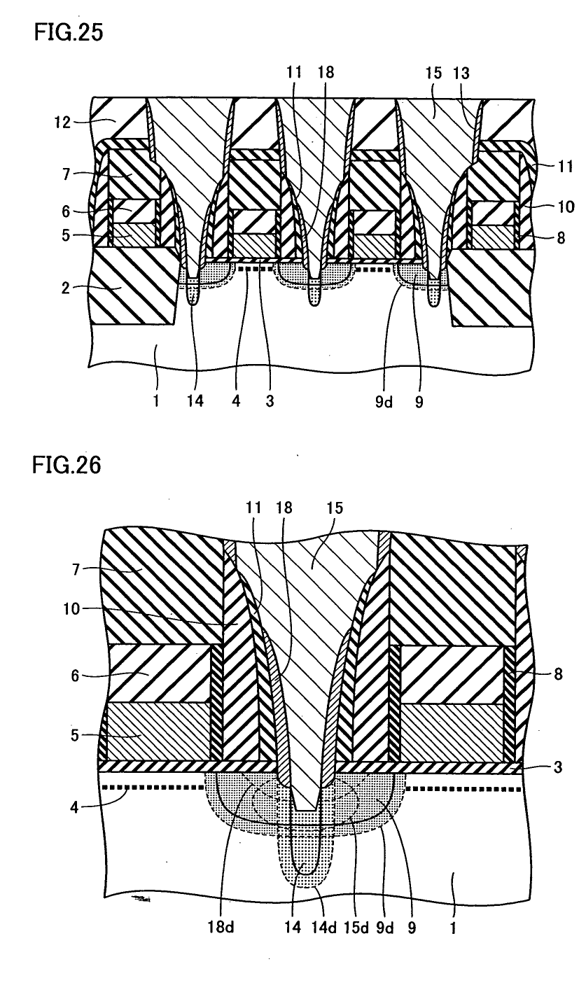

Then, as shown in FIG. 24, the N-type impurity such as P is injected to semiconductor substrate 1 exposed on the bottom portion of contact hole 13. Thus, N-type impurity region 14 is formed under contact hole 13. Similarly to Embodiment 1, polysilicon doped with the N-type impurity is deposited as the plug material, and plug 15 is thus formed as shown in FIG. 25. An enlarged view of the vicinity of the bottom portion of plug 15 in FIG. 25 is shown in FIG. 26.

In the semiconductor device obtained by the manufacturing method of the semiconductor device in the present embodiment, or in the semiconductor device in the present embodiment, diffusion prevention film 18 extends downward so as to be introduced into semiconductor substrate 1. Moreover, since diffusion prevention film 18 is composed of polysilicon doped with boron as the P-type impurity, boron diffuses from diffusion prevention film 18, to form a P-type boron diffusion region 18d, as shown in FIG. 26. Boron diffusion region 18d extends farther toward the side direction particularly in the vicinity of the surface of semiconductor substrate 1. By forming such boron diffusion region 18d, punchthrough is more unlikely than in Embodiment 1.

### Embodiment 4

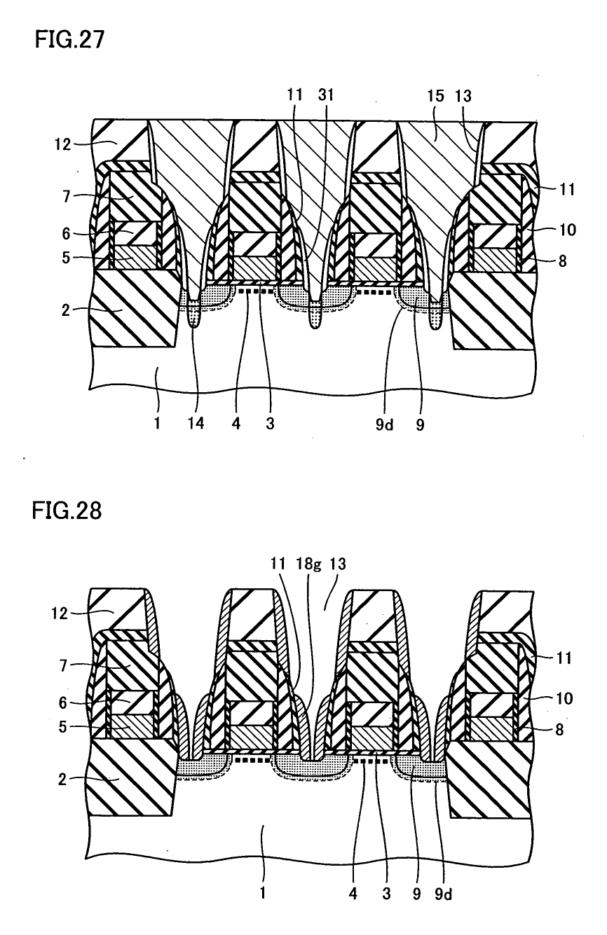

A manufacturing method of a semiconductor device in Embodiment 4 according to the present invention will be described. In Embodiment 3, diffusion prevention film 18 has been formed with the boron-doped polysilicon with respect to the structure in FIG. 9. In the present embodiment, instead, a diffusion prevention film of a similar shape is formed with undoped polysilicon. As a result, a semiconductor device shown in FIG. 27 can be obtained.

In the present embodiment, diffusion from the diffusion prevention film to the semiconductor substrate as described with reference to FIG. 26 in Embodiment 3 does not take place. On the other hand, the side face of plug 15 containing the N-type impurity to fill contact hole 13 later is located in a position farther from the end of gate electrode 5. Therefore, compared with the structure in which the plug is directly formed without the diffusion prevention film, punchthrough resistance will be higher.

### Embodiment 5

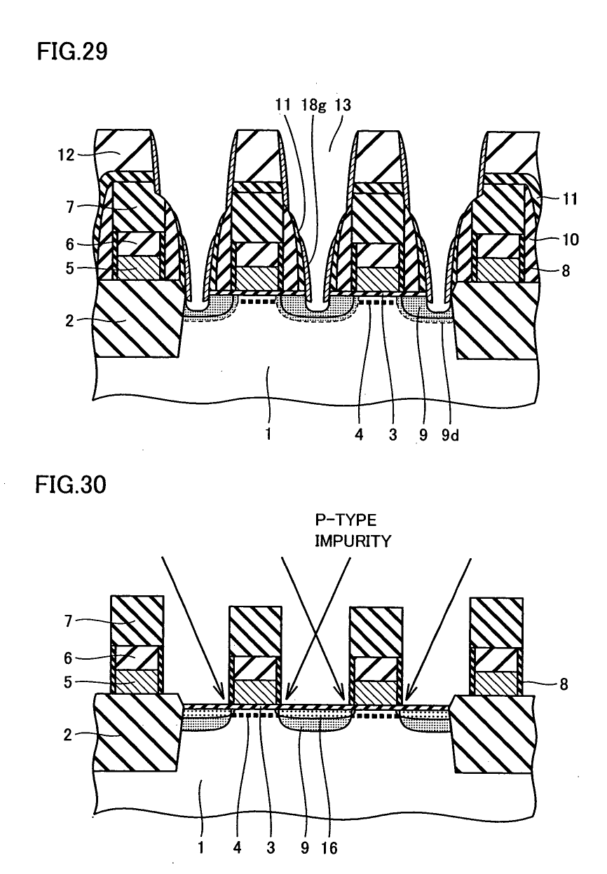

A manufacturing method of a semiconductor device in Embodiment 5 according to the present invention will be described. In Embodiment 3, boron-doped polysilicon used as the material for diffusion prevention film 18 has been deposited to a thickness of approximately 5 nm on the entire surface of the structure in FIG. 9, to obtain boron-doped polysilicon film 18f (see FIG. 22). In the present embodiment, however, boron-doped polysilicon is deposited to a thickness of approximately 45 nm on the entire surface, to obtain a boron-doped polysilicon film 18g. Anisotropic dry etching is then performed, and is stopped at a stage where semiconductor substrate 1 is exposed by removing boron-doped polysilicon film 18g on the bottom face of the contact hole, as shown in FIG. 28. In addition, semiconductor substrate 1 exposed on the bottom face of contact hole 13 is subjected to wet etching. As wet etching progresses in an isotropic manner, the bottom portion of contact hole 13 is etched also laterally, to attain a shape as shown in FIG. 29. Thickness of boron-doped polysilicon film 18g in FIG. 29 is smaller than in FIG. 28, because the film has been removed in wet etching. In the present embodiment, considering this fact, initial thickness of boron-doped polysilicon film 18g has been set to 45 nm. Process steps subsequent to a state shown in FIG. 29 are similar to those in Embodiment 2.

The present embodiment adopts structures in both Embodiments 2 and 3, and accordingly, can attain effects obtained from the both embodiments.

### Embodiment 6

Referring to FIGS. 1 to 5, FIG. 30, FIGS. 6 to 10 and 31 to 34, a manufacturing method of a semiconductor device in Embodiment 6 according to the present invention will be described. The process steps shown in FIGS. 1 to 5 are similar to those described in Embodiment 1. In Embodiment 1, sidewall spacer 10 has been formed with respect to the structure in FIG. 5 (see FIG. 6). In the present embodiment, however, the P-type impurity such as boron is diagonally injected from above onto the structure in FIG. 5, and a P-type impurity region 16 is formed in the vicinity of the surface of semiconductor substrate 1 exposed in a gap between gate electrodes 5, as shown in FIG. 30. Though P-type impurity region 16 is formed with a depth smaller than source/drain region 9, it has a horizontal length larger than source/drain region 9, because of the injection in a diagonal direction. That is, the impurity region extends to a position under gate electrode 5 to some extent.

With the process steps similar to those as described with reference to FIGS. 6 to 10 in Embodiment 1, sidewall spacer 10, nitride film 11, interlayer insulating film 12, contact hole 13, and nitride film 17f are successively formed. Here, a difference from Embodiment 1 is that P-type impurity region 16 is present.

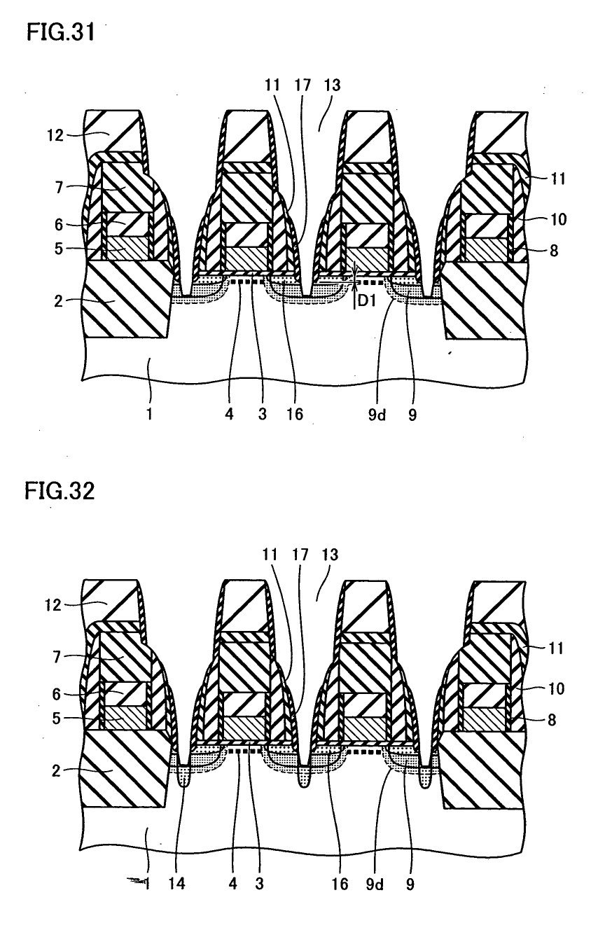

Next, anisotropic dry etching is performed on nitride film 17f on its entire surface, and diffusion prevention film 17 is formed by the remaining portion of nitride film 17f, as shown in FIG. 31. As a result, the lower end of diffusion prevention film 17 is introduced in a position lower by D1 than the upper surface of semiconductor substrate 1 in other regions. Anisotropic dry etching for forming diffusion prevention film 17 with respect to semiconductor substrate 1 is performed such that even source/drain region 9 is etched after P-type impurity region 16 is etched through.

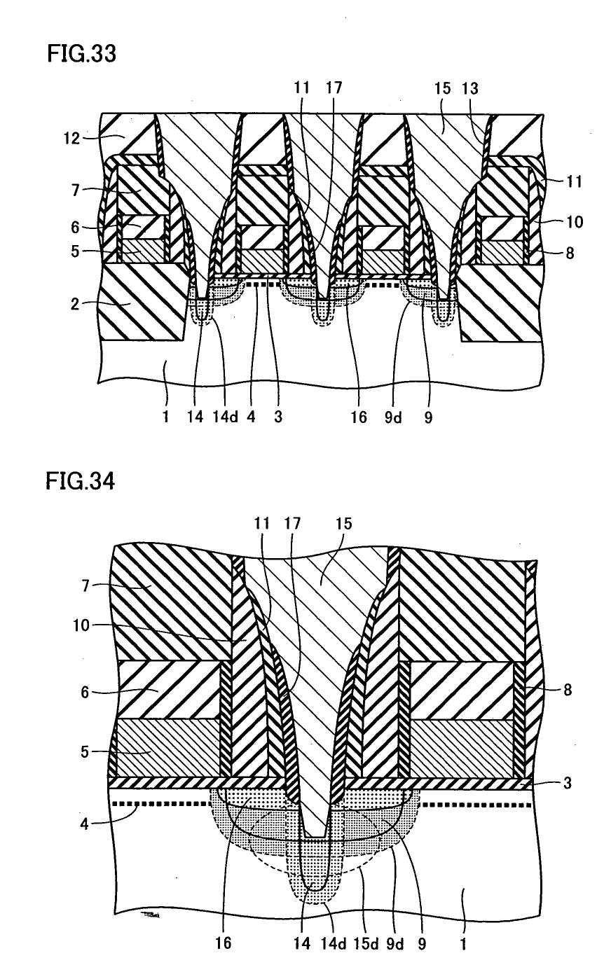

As shown in FIG. 32, the N-type impurity such as P is injected into semiconductor substrate 1 exposed on the bottom portion of contact hole 13, to form N-type impurity region 14. As shown in FIG. 33, plug 15 is formed within contact hole 13. An enlarged view of the vicinity of the bottom portion of contact hole 13 in FIG. 33 is shown in FIG. 34. The impurity diffuses from each of N-type impurity region 14, source/drain region 9 and plug 15, and diffusion portions 14d, 9d, and 15d are produced respectively.

The semiconductor device in the present embodiment includes P-type impurity region 16 as shown in FIGS. 33 and 34. P-type impurity region 16 extends such that a part thereof reaches a position directly under gate electrode 5. The structure is otherwise the same as that in the semiconductor device described in Embodiment 1.

In the semiconductor device obtained by the manufacturing method of the semiconductor device in the present embodiment, or in the semiconductor device in the present embodiment, punchthrough is unlikely by virtue of presence of P-type impurity region 16. In other words, punchthrough resistance is higher.

If P-type impurity region 16 is simply provided and depth of contact hole 13 is set as conventional, a position where plug 15 comes in contact with semiconductor substrate 1 would be inside P-type impurity region 16. In such a case, though an effect of higher punchthrough resistance can be obtained, contact resistance increases. In the present embodiment, however, the bottom portion of contact hole 13 is formed so as to reach source/drain region 9, penetrating P-type impurity region 16. Therefore, a problem of the increase of the contact resistance can be avoided. In addition, since a contact area between plug 15 and semiconductor substrate 1 is made larger by etching semiconductor substrate 1 deeper, contact resistance can be reduced.

The present embodiment can also obtain the effect described in Embodiment 1. The effect obtained when diffusion prevention film 17 is formed with the oxide film instead of the nitride film is also similar, as described in Embodiment 1. In addition, the effect on the cavity created by insufficient embedding of interlayer insulating film 12 is also similar, as described in Embodiment 1.

Here, in the present embodiment as well, a concept in Embodiment 2 may be incorporated. In other words, in anisotropic dry etching for forming diffusion prevention film 17, anisotropic dry etching is once stopped at a stage where semiconductor substrate 1 is exposed, and subsequent etching of semiconductor substrate 1 may be carried out by wet etching. In such a case, an effect described in Embodiment 2 can further be obtained besides the effects described above.

### Embodiment 7

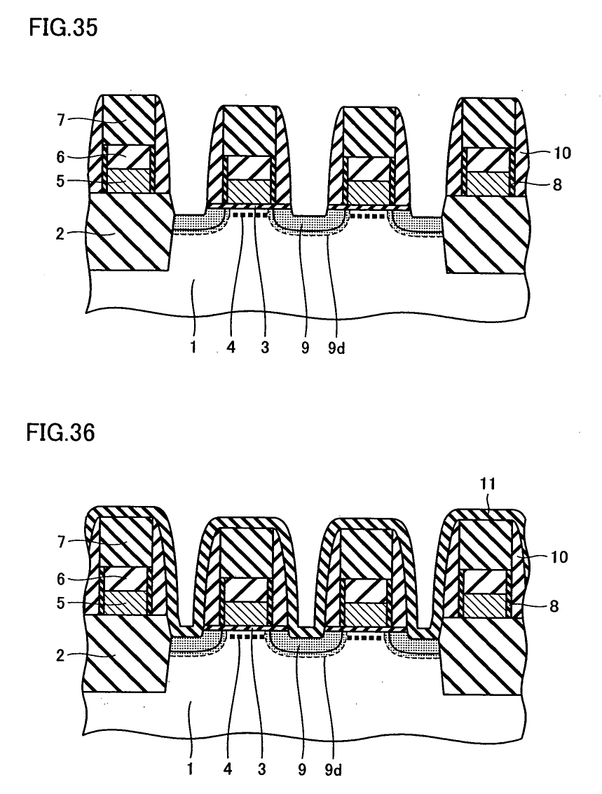

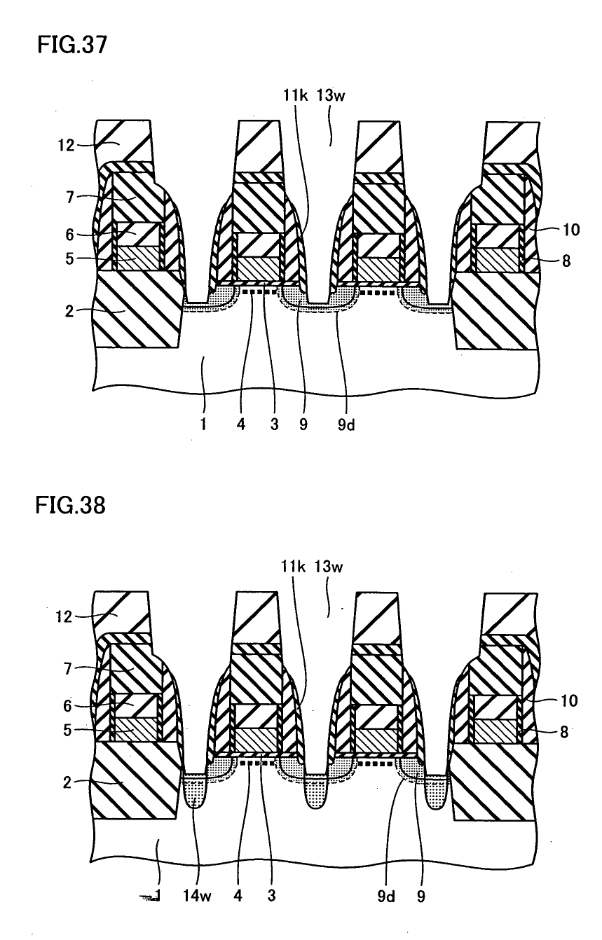

Referring to FIGS. 1 to 5 and 35 to 40, a manufacturing method of a semiconductor device in Embodiment 7 according to the present invention will be described. The process steps shown in FIGS. 1 to 5 are similar to those described in Embodiment 1. In Embodiment 1, the nitride film is deposited to a thickness of 20 nm on the entire surface with respect to the structure in FIG. 5, and anisotropic dry etching is performed until gate oxide film 3 is exposed, to form sidewall spacer 10 (see FIG. 6). In the present embodiment, however, anisotropic dry etching is performed not until gate oxide film 3 is exposed but until gate oxide film 3 is removed and semiconductor substrate 1 is etched by approximately 20 nm. As a result, a structure shown in FIG. 35 is obtained. In this state, as shown in FIG. 36, nitride film 11 as a stopper film is deposited to a thickness of 15 nm on the entire surface. In addition, interlayer insulating film 12 composed of BPTEOS is deposited to a thickness of 500 nm, followed by anisotropic dry etching on the entire surface. A diffusion prevention film 11k is then formed by the remaining portion of nitride film 11, as shown in FIG. 37. Anisotropic dry etching for forming diffusion prevention film 11k is performed to reach a position deeper by approximately 30 nm from the lower end of diffusion prevention film 11k. A contact hole 13w is thus formed.

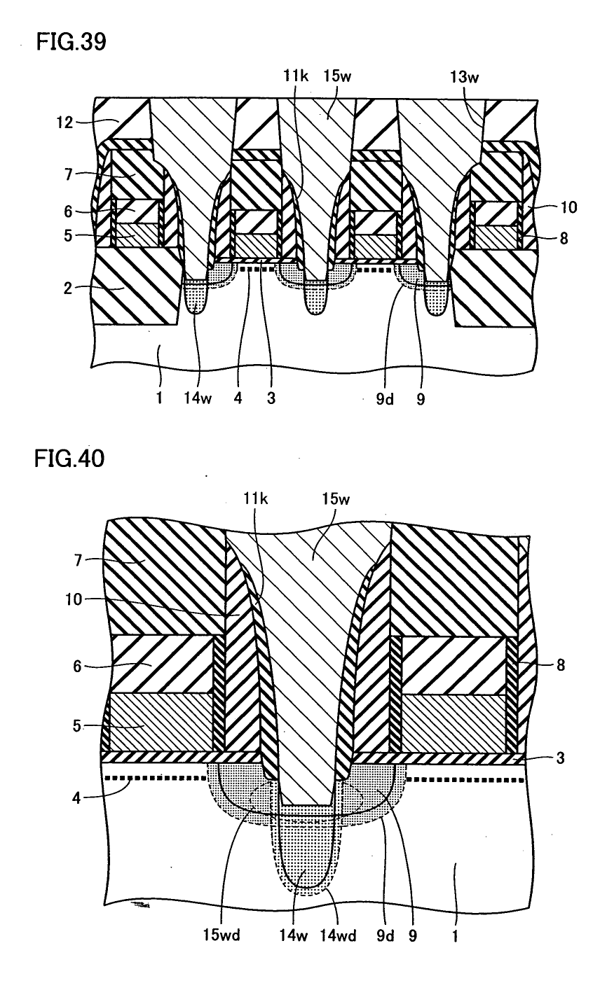

Next, as shown in FIG. 38, the N-type impurity such as P is injected to semiconductor substrate 1 exposed on the bottom portion of contact hole 13w, to form an N-type impurity region 14w under contact hole 13w. Similarly to Embodiment 1, a plug 15w is formed within contact hole 13w as shown in FIG. 39. An enlarged view of the vicinity of the bottom portion of contact hole 13w in FIG. 39 is shown in FIG. 40. The impurity diffuses from each of N-type impurity region 14w, source/drain region 9 and plug 15w, and diffusion portions 14wd, 9d, and 15wd are produced respectively.

In the semiconductor device obtained by the manufacturing method of the semiconductor device in the present embodiment, diffusion prevention film 11k extends downward so as to be introduced into semiconductor substrate 1. Therefore, diffusion from plug 15w to semiconductor substrate 1 takes place only from a portion where plug 15w extends below diffusion prevention film 11k. Accordingly, as can be seen from the shape of diffusion portion 15wd in FIG. 40, diffusion along the surface of semiconductor substrate 1 is suppressed to a small area. Consequently, punchthrough is unlikely, as in Embodiment 1. In other words, punchthrough resistance is high. In addition, GIDL can be prevented as in Embodiment 1. Further, the nitride film as the stopper film for forming contact hole 13w in a self-aligned manner serves also as the diffusion prevention film. Therefore, even if the arrangement or size of gate electrode 5 is set as conventional, contact hole 13w with larger width can be formed. As a result, contact area between plug 15w and semiconductor substrate 1 in the bottom portion of contact hole 13w can be made larger, and contact resistance can further be reduced, compared with Embodiment 1.

Here, in the present embodiment as well, a concept in Embodiment 2 may be incorporated. In other words, anisotropic dry etching for forming diffusion prevention film 11k is once stopped at a stage where semiconductor substrate 1 is exposed, and subsequent etching of semiconductor substrate 1 may be carried out by wet etching. In such a case, an effect described in Embodiment 2 can further be obtained besides the effects described above.

### Embodiment 8

Referring to FIGS. 1 to 5, FIG. 30 and FIGS. 41 to 45, a manufacturing method of a semiconductor device in Embodiment 8 according to the present invention will be described. The present embodiment combines the concepts in Embodiments 6 and 7, and includes process steps common to Embodiment 6, up to steps halfway in the process. In other words, the process steps shown in FIGS. 1 to 5 are similar to those described in Embodiment 1, as also stated in Embodiment 6. In the present embodiment, as in Embodiment 6, the P-type impurity such as boron is diagonally injected from above onto the structure in FIG. 5, and P-type impurity region 16 is formed in the vicinity of the surface of semiconductor substrate 1 exposed in a gap between gate electrodes, 5 as shown in FIG. 30.

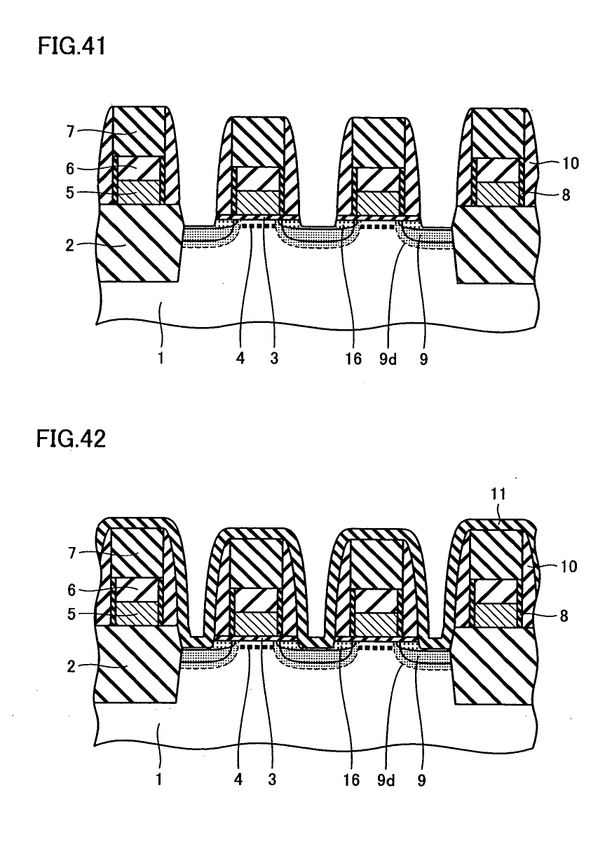

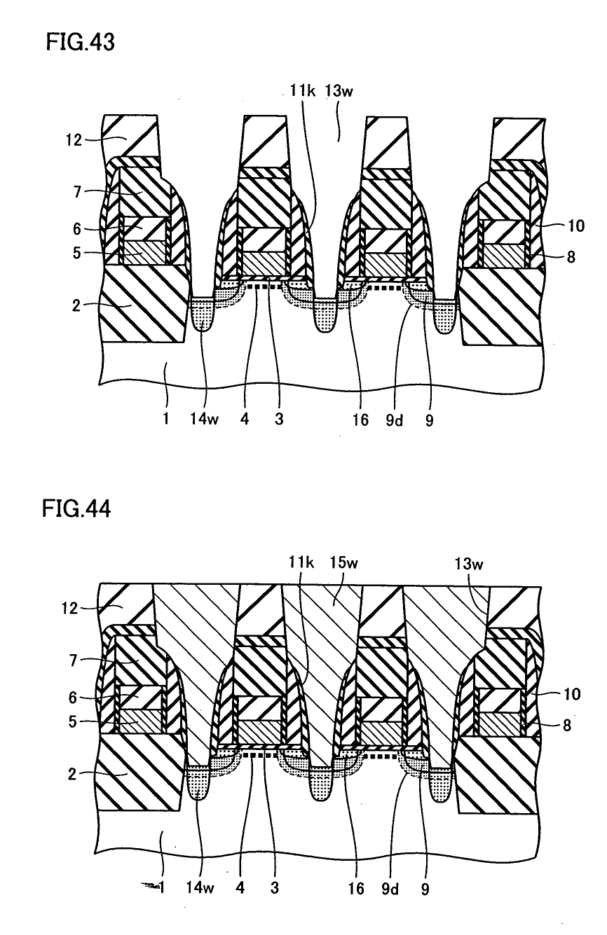

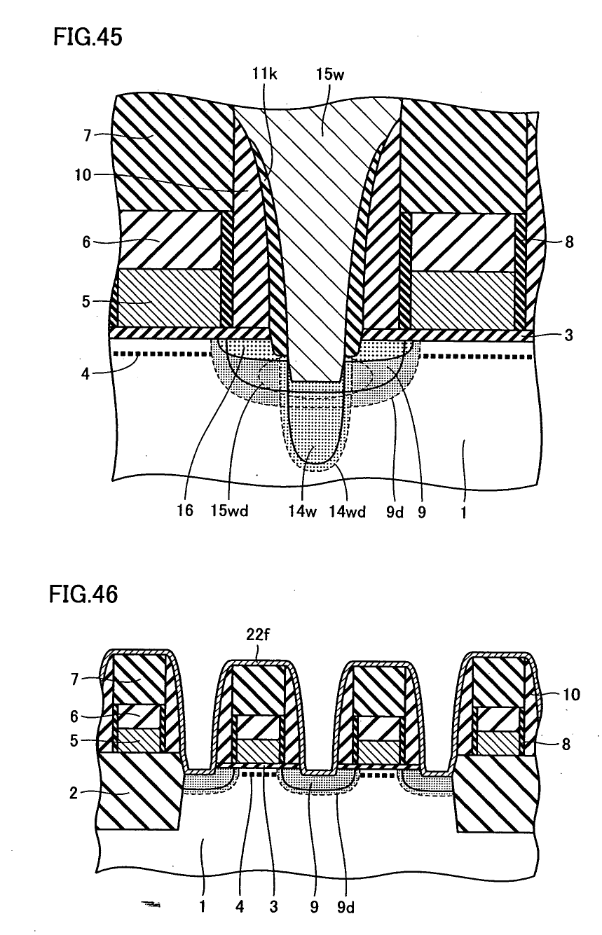

Thereafter, as in Embodiment 1, sidewall spacer 10 is formed. In Embodiment 1, however, when sidewall spacer 10 is formed from the nitride film by anisotropic dry etching, anisotropic dry etching has been stopped at a stage where gate oxide film 3 is exposed, as shown in FIG. 6. In the present embodiment, however, anisotropic dry etching is not stopped here, and instead, gate oxide film 3 exposed as shown in FIG. 41 is removed, and semiconductor substrate 1 is etched to a depth of approximately 20 nm. Next, as shown in FIG. 42, nitride film 11 as a stopper film is deposited to a thickness of 15 nm on the entire surface. In addition, interlayer insulating film 12 composed of BPTEOS is deposited to a thickness of 500 nm, followed by anisotropic dry etching on the entire surface. Diffusion prevention film 11k is then formed by the remaining portion of nitride film 11, as shown in FIG. 43. Anisotropic dry etching for forming diffusion prevention film 11k is performed to reach a position deeper by approximately 30 nm than the lower end of diffusion prevention film 11k. Contact hole 13w is thus formed. The N-type impurity such as P is injected into semiconductor substrate 1 exposed on the bottom portion of contact hole 13w, and N-type impurity region 14w is formed under contact hole 13w. Further, similarly to Embodiment 1, as shown in FIG. 44, plug 15w is formed in contact hole 13w. An enlarged view of the vicinity of the bottom portion of contact hole 13w in FIG. 44 is shown in FIG. 45. The impurity diffuses from each of N-type impurity region 14w, source/drain region 9 and plug 15w, and diffusion portions 14wd, 9d, and 15wd are produced respectively.

In the present embodiment, effects described in Embodiments 6 and 7 can both be obtained.

Here, in the present embodiment as well, a concept in Embodiment 2 may be incorporated. In other words, anisotropic dry etching for forming diffusion prevention film 11k is once stopped at a stage where semiconductor substrate 1 is exposed, and subsequent etching of semiconductor substrate 1 may be carried out by wet etching. In such a case, an effect described in Embodiment 2 can further be obtained besides the effects described above.

### Embodiment 9

Referring to FIGS. 1 to 5, FIG. 35 and FIGS. 46 to 51, a manufacturing method of a semiconductor device in Embodiment 9 according to the present invention will be described. The present embodiment combines and applies the concepts in Embodiments 3 and 7.

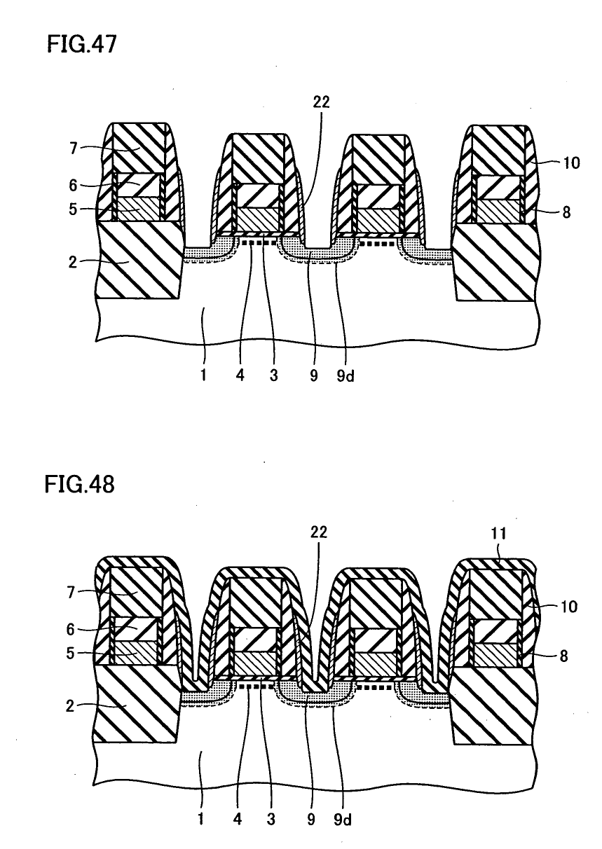

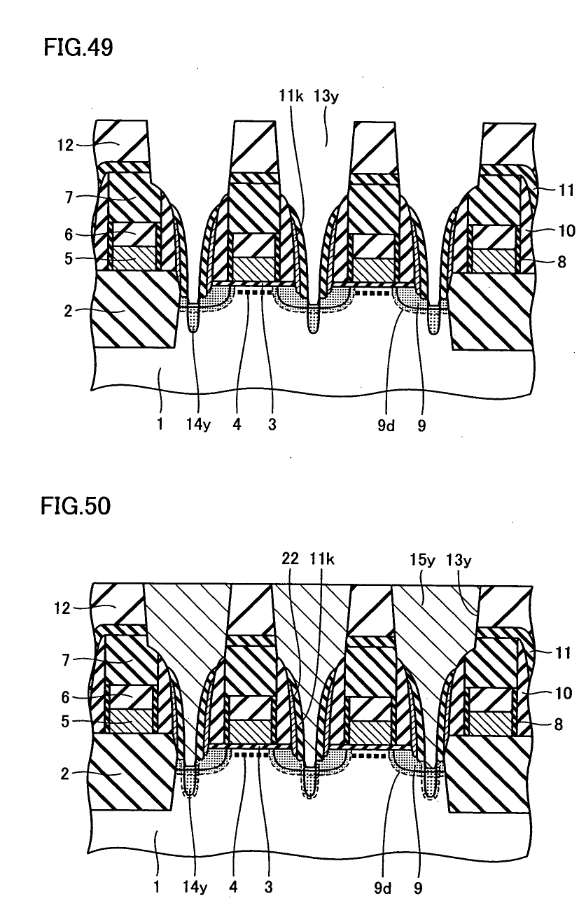

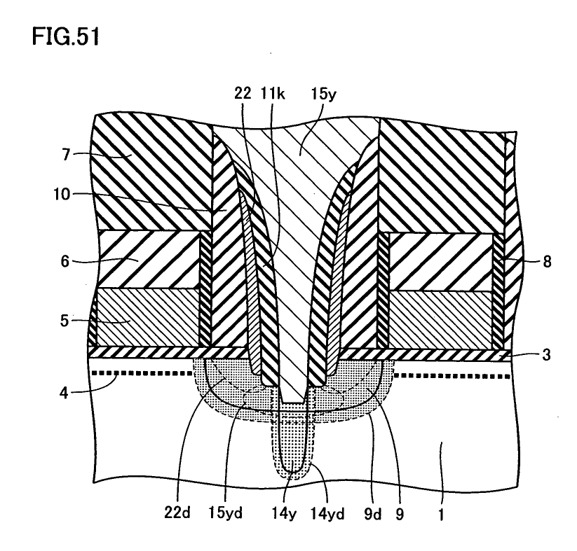

The present embodiment is similar to Embodiment 7 up to the etching step, in which semiconductor substrate 1 is etched to a depth of approximately 20 nm by anisotropic dry etching for forming sidewall spacer 10 as shown in FIG. 35, after the process steps shown in FIGS. 1 to 5. Next, as shown in FIG. 46, a boron-doped polysilicon film 22f is deposited to a thickness of approximately 5 nm on the entire surface, and subjected to overall, anisotropic dry etching, so that a diffusion prevention film 22 is formed by the remaining portion of boron-doped polysilicon film 22f, as shown in FIG. 47. In this state, nitride film 11 as a stopper film is deposited to a thickness of 15 nm on the entire surface, as shown in FIG. 48. In addition, interlayer insulating film 12 composed of BPTEOS is deposited to a thickness of 500 nm, followed by anisotropic dry etching on the entire surface. Diffusion prevention film 11k is then formed by the remaining portion of nitride film 11, as shown in FIG. 49. Anisotropic dry etching for forming diffusion prevention film 11k is performed to reach a position deeper by approximately 30 nm than the lower end of diffusion prevention film 11k. A contact hole 13y is thus formed. The N-type impurity such as P is injected into semiconductor substrate 1 exposed on the bottom portion of contact hole 13y, to form an N-type impurity region 14y. Further, similarly to Embodiment 1, as shown in FIG. 50, a plug 15y is formed in contact hole 13y. An enlarged view of the vicinity of the bottom portion of contact hole 13y in FIG. 50 is shown in FIG. 51. The diffusion prevention film here has a dual structure of diffusion prevention film 22 and diffusion prevention film 11k. The impurity diffuses from each of N-type impurity region 14y, source/drain region 9 and plug 15y, and diffusion portions 14yd, 9d, and 15yd are produced respectively. As diffusion prevention film 22 is composed of polysilicon doped with boron as the P-type impurity, boron diffuses from diffusion prevention film 22, and a P-type boron diffusion region 22d is formed as shown in FIG. 51.

Though a contact area between the plug and the semiconductor substrate is slightly smaller in the present embodiment than in Embodiment 7, effects similar to those described in Embodiment 7 can otherwise be obtained. In addition, as boron diffusion region 22d is formed, punchthrough is more unlikely than in Embodiment 7.

Here, in the present embodiment as well, a concept in Embodiment 2 may be incorporated. In other words, anisotropic dry etching for forming diffusion prevention film 11k is once stopped at a stage where semiconductor substrate 1 is exposed, and subsequent etching of semiconductor substrate 1 may be carried out by wet etching. In such a case, an effect described in Embodiment 2 can further be obtained besides the effects described above.

According to the present invention, a semiconductor device with a structure in which the diffusion prevention film extends downward so as to be introduced into the semiconductor substrate in a contact portion can be obtained. In the semiconductor device with such a structure, diffusion from the plug to the semiconductor substrate takes place only from a portion in which the plug extends below the diffusion prevention film. Therefore, diffusion along the surface of the semiconductor substrate is suppressed to a small area. Consequently, the semiconductor device with high punchthrough resistance can be obtained. In addition, when the diffusion prevention film is introduced into the semiconductor substrate, the plug is shielded from the outside on the surface of the semiconductor device. Therefore, GIDL can also be prevented. Further, a large contact area between the plug and the semiconductor substrate can be ensured, and contact resistance can be reduced.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of manufacturing a semiconductor device, comprising the steps of:
forming a plurality of projected gate portions by forming a plurality of gate electrodes in a line shape in parallel on a gate oxide film formed so as to cover a main surface of a semiconductor substrate and by forming a sidewall spacer serving as an insulating film covering a side of said gate electrode;
forming an interlayer insulating film covering an upper side of said projected gate portion and a gap between said projected gate portions, with respect to said projected gate portion;
forming a contact hole reaching a first bottom portion introduced into said semiconductor substrate, from an upper surface of said interlayer insulating film through the gap between said projected gate portions;
forming a second bottom portion having said semiconductor substrate exposed on a bottom face and a side face by forming a diffusion prevention film covering a side face of said first bottom portion and by etching further a bottom face of said first bottom portion; and
forming a plug by filling said contact hole with polysilicon having an impurity doped.

2. The method of manufacturing a semiconductor device according to claim 1, wherein
said step of forming the second bottom portion by etching is performed by wet etching.

3. The method of manufacturing a semiconductor device according to claim 1, wherein
undoped polysilicon is used as said diffusion prevention film.

4. The method of manufacturing a semiconductor device according to claim 1, wherein
polysilicon doped with boron is used as said diffusion prevention film.

5. The method of manufacturing a semiconductor device according to claim 1, further comprising the step of diagonally injecting a P-type impurity onto said gate oxide film exposed between said gate electrodes prior to forming said sidewall spacer, to form a region having the P-type impurity doped so as to extend to a position directly under said gate electrode.

6. The method of manufacturing a semiconductor device according to claim 1, further comprising the step of injecting an N-type impurity onto a bottom face of said contact hole, prior to said step of forming a plug.

7. A method of manufacturing a semiconductor device, comprising the steps of:
forming a sidewall spacer covering a side of each of a plurality of gate electrodes formed in a line shape in parallel on a gate oxide film formed so as to cover a main surface of a semiconductor substrate, and forming a first bottom portion introduced into said semiconductor substrate through said gate oxide film exposed between said gate electrodes;
forming a stopper film covering an upper side of said semiconductor substrate including said first bottom portion;
forming an interlayer insulating film covering an upper side of said stopper film;
forming a contact hole reaching said stopper film from an upper surface of said interlayer insulating film through a gap between said gate electrodes;
forming a second bottom portion having said semiconductor substrate exposed on a bottom face and a side face by forming a diffusion prevention film covering a side face of said first bottom portion by partially removing said stopper film and by etching further a bottom face of said first bottom portion; and
forming a plug by filling said contact hole with polysilicon having an impurity doped.

8. The method of manufacturing a semiconductor device according to claim 7, wherein
the step of forming said second bottom portion by etching is performed by wet etching.

9. A semiconductor device, comprising:
a semiconductor substrate;
a plurality of gate electrodes formed in a line shape in parallel on said semiconductor substrate, with a gate insulating film interposed;
a plug electrode formed in a gap between said gate electrodes with polysilicon having an impurity doped, so that a lower end of the plug electrode is introduced into said semiconductor substrate; and
a diffusion prevention film extending so as to cover a side face of said plug electrode in a vicinity of the lower end of said plug electrode, and so as to be introduced into said semiconductor substrate.

10. The semiconductor device according to claim 9, further comprising a region where a P-type impurity is doped, so as to extend to a position directly under said gate electrode.

11. The semiconductor device according to claim 9, wherein an N-type impurity is injected into a portion in contact with the lower end of said plug electrode in said semiconductor substrate.
